(19) United States
(12) Patent Application Publication
(10) Pub. No.: US 2009/0246515 A1
(43) Pub. Date: Oct. 1, 2009

(54) Neuroelectrode Coating and Associated Methods

(76) Inventors: Sandeep Negi, Salt Lake City, UT (US); Rajmohan Bhandari, Salt Lake City, UT (US); Florian Solzbacher, Salt Lake City, UT (US)

Correspondence Address: THORPE NORTH & WESTERN, LLP., P.O. Box 1219, SANDY, UT, 84091-1219, US

(21) Appl. No.: 12/334,208

(22) Filed: Dec. 12, 2008

Related U.S. Application Data
(60) Provisional application No. 61/013,241, filed on Dec. 12, 2007.

(51) Int. Cl. C23C 14/34; C25F 1/00; B32B 9/00

(52) U.S. Cl. 428/336; 204/192.15; 205/766; 428/702

(57) ABSTRACT

Micro-neuroelectrodes for use in stimulation of neurons can be formed having decreased impedance, increased charge storage capacity, and good durability. A method of coating a micro-neuroelectrode includes sputtering a film of iridium oxide on a surface of the micro-neuroelectrode. The sputtering can occur using pulse-DC conditions under reactive conditions that are sufficient to form a polycrystalline iridium oxide film that adheres to the surface of the micro-neuroelectrode. The deposited iridium oxide film can also be optionally activated to increase its charge storage capacity.

### RELATED APPLICATIONS

This application claims the benefit of U.S. Provisional Patent Application No. 61/013,241, filed on Dec. 12, 2007, which is incorporated by reference herein in its entirety.

### FEDERALLY SPONSORED RESEARCH

This invention was made with government support under Grant NS042632 awarded by the National Institutes of Health and Award N66001-05-C-8045 awarded by the Department of Defense. The Government has certain rights to this invention.

### FIELD OF THE INVENTION

This invention relates to coatings and films for microelectrodes and methods for producing the coatings.

### BACKGROUND OF THE INVENTION

Neuroprosthetic implants can be useful in recording and stimulating neurons for a wide variety of applications. Such applications can range from systems which monitor neurological behavior to stimulating neurological activity in response to provided signals such as for stabilizing erratic neurosignals or activating muscle responses. The artificial stimulation of living tissue requires transfer of an external electrical signal from an implantable electro-conductive microelectrode to the neural cells. Therefore, the interface between an electrode and a neural cell, e.g. brain fluid, is an important part of the stimulating device and is one factor for device performance. Although a number of interfaces have been tried, many pose problems such as heightened threshold, heightened impedance, low resistance to degrading in biological material, etc. Therefore, methods and devices which improve signal behavior in neuroelectrodes continue to be sought.

### SUMMARY OF THE INVENTION

An improved interface between electrode and biological matter has been created. The interface is in the form of a coating which can improve stability as well as activity of a micro-neuroelectrode in use. As such, a method of coating a micro-neuroelectrode is presented herein. The method includes sputtering a film of iridium oxide on a surface of the micro-neuroelectrode. The sputtering can be pulsed DC reactive sputtering under reactive conditions. The sputtering conditions can be selected or configured to form a polycrystalline iridium oxide film adhering to the surface of the micro-neuroelectrode.

Similarly, a coated micro-neuroelectrode can include a micro-neuroelectrode and a polycrystalline iridium oxide coating on an exposed surface of the neuroelectrode. The micro-neuroelectrode can have an exposed surface configured to interface with biological matter such as neurotissue. The iridium oxide film can have an impedance of less than about 20 kΩ. Such a micro-neuroelectrode exhibits long-term stability and resistance to degradation, as well as improved performance characteristics such as, e.g., lower threshold durations and improved charge capacity.

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying drawings and claims, or may be learned by the practice of the invention.

### BRIEF DESCRIPTION OF THE DRAWINGS

FIG. 1 is an SEM of a sputtered iridium oxide film (SIROF) coated neuro-microelectrode in accordance with one embodiment of the present invention.

FIG. 2 is a magnified SEM view of the SIROF coated neuro-microelectrode of FIG. 1, in accordance with one embodiment of the present invention.

FIG. 3 is a graph of measured average electro-chemical impedance of 96 electrodes in an array in accordance with one embodiment of the present invention. The average impedance was 8.7 kΩ and 1 kHz with standard deviation of 3.65 kΩ.

FIG. 4 is a graph of cathodal charge injection capacity (CCSC) of 96 electrodes in an array in accordance with one embodiment of the present invention. The average CCSC of an array was 38.98 mC/cm² with standard deviation of 14.25 mC/cm².

FIG. 5 is a Bode plot of one electrode of a SIROF coated Utah electrode array (UEA) soaked in phosphate buffered saline (PBS) solution for 35 days in accordance with one embodiment of the present invention. As seen in the plot there is no change in impedance magnitude and phase indicating that the SIROF is stable in the solution.

### DETAILED DESCRIPTION

Reference will now be made to exemplary embodiments, and specific language will be used herein to describe the same. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

### DEFINITIONS

In describing and claiming the present invention, the following terminology will be used in accordance with the definitions set forth below. It will nevertheless be understood that no limitation of the scope of the invention is thereby intended. Alterations and further modifications of the inventive features illustrated herein, and additional applications of the principles of the inventions as illustrated herein, which would occur to one skilled in the relevant art and having possession of this disclosure, are to be considered within the scope of the invention.

It must be noted that, as used in this specification and the appended claims, the singular forms “a,” “an,” and “the” include plural referents unless the context clearly dictates otherwise. Thus, for example, reference to “a neuron” includes one or more of such neurons, reference to “an electrode” includes reference to one or more of such electrodes, and reference to “a pre-treating step” includes reference to one or more of such steps.

As used herein, the term “threshold” refers to an electrical stimulation which causes depolarization of membrane potential in a neuron (including an axon) sufficient to evoke an action potential or nerve impulse. Action potential is evoked when a certain amount of charge is injected to the nerve tissue. A threshold can be reached by charging an electrode with a voltage for a given time to produce a charge (i.e. current times time). Either or both the voltage and time can be varied to reach threshold. Thus, threshold duration or threshold time indicates the time to threshold for a corresponding voltage. Similarly, threshold voltage indicates the applied voltage for a corresponding time. Each of the time and voltage are dependent on the other, although the threshold for a given neuron is typically substantially fixed within the timescale involved herein. With respect to the present invention, different electrode materials can exhibit varying threshold durations under the same applied voltage before reaching threshold. In particular, an anodic iridium oxide film (hereinafter “AIROF”) has a significantly higher threshold duration than a sputtered iridium oxide film (hereinafter “SIROF”) of the present invention for the same constant threshold voltage. It also appears as though higher threshold duration and/or voltage can cause damage to stimulated neurons.

The term “micro” in relation to electrodes, and particularly in relation to micro-neuroelectrodes, describes electrodes having a size dimension in the micron scale, i.e. less than 1000 μm. Specifically, the electrodes have a size of from about tens of microns up to about 1.5 mm, although the conductive exposed surface at the tips are generally sub-micron (i.e. less than one micron). Typically, for a 1.5 mm length electrode, a SIROF film can be coated over a portion of that length from about 10 μm to about 100 μm and often from 30-60 μm.

As used herein, “substantial” when used in reference to a quantity or amount of a material, or a specific characteristic thereof, refers to an amount that is sufficient to provide an effect that the material or characteristic was intended to provide. The exact degree of deviation allowable may in some cases depend on the specific context. Similarly, “substantially free of” or the like refers to the lack of an identified element or agent in a composition. Particularly, elements that are identified as being “substantially free of” are either completely absent from the composition, or are included only in amounts which are small enough so as to have no measurable effect on the composition.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, thicknesses, parameters, volumes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc. This same principle applies to ranges reciting only one numerical value. Furthermore, such an interpretation should apply regardless of the breadth of the range or the characteristics being described.

### INVENTION

The present invention provides a method of coating a micro-neuroelectrode and the resulting micro-neuroelectrodes. Methods in accordance with the present invention include sputtering a film of iridium oxide on a surface of the micro-neuroelectrode. The film can be formed through pulsed DC reactive sputtering. Such film formation conditions can form a polycrystalline iridium oxide film adhering to the surface of the micro-neuroelectrode.

The method of deposition as outlined herein is sputtering. Within sputtering, there are three distinct types: DC, RF, and pulsed DC. Each of these approaches can produce distinct results in film properties. In the present invention, iridium oxide films are formed using pulsed DC reactive sputtering. One advantage of using pulsed DC power as opposed to DC power is to prevent the formation of arcs. Pulsed DC power supplies avoid these problems by including positive voltage phase for a brief period of time, referred to as the duty-cycle. This positive bias allows a charge to be built up on the dielectric material which is unintentionally deposited on the target. During negative bias periods, greater numbers of sputtering ions are pulled to this localized extra charge, preferentially sputtering the ‘poisoned’ dielectric material off, exposing the pure metal again. Pulsed DC reactive sputtering can be used to deposit in a manner that results in a smooth structure due to the absence of particulates created by arcing.

On the contrary, reactive DC sputtering (not pulsed DC) has been hindered due to ‘target poisoning’. Though the reacted material in a sputtering chamber can be directed towards a substrate with high accuracy, the nature of the process allows some material to fall back onto the target. The dielectric material electrically insulates the target from the plasma stopping local sputtering or ‘poisoning’ the target causing an arc. The arcs result in macro- or micro-particulates in the deposited films, which results in the non-uniform film property across a sample. These particulates make the film characteristics unpredictable and irreproducible. Additionally, the arcs can damage the target, power supply, and deposited films. As such, the present disclosure is directed to pulsed DC reactive sputtering, which deposits films in a smooth, reproducible manner and without forming arcs.

Pulsed DC reactive sputtering is a method of growing or forming a layer of material on a suitable substrate such as a metallic, ceramic, or semi-metal substrate. To effectively form a sputtered layer, a reactive gas, such as oxygen, is introduced into the reaction chamber during sputtering of a source material target, e.g. an iridium plate. The reaction between the reactive gas and sputtered atoms at a surface of an electrode forms a reacted species layer, in this case, iridium oxide. Deposition conditions and parameters can be altered and optimized to form layers of iridium oxide with varying properties, as desired.

Electrodes configured for use in biological matter can be configured to withstand the harsh biological environments, while still maintaining desired functionality. In order to protect the stability of an electrode, the outer surface or surfaces of the electrode can be covered in a film formulated to provide the desired protection and long-term stability. Unfortunately, many films that may be used to protect the electrode in the biological environment drastically reduce the functionality of the electrode. In certain embodiments, therefore, a film can be formed on an outer surface of an electrode that does not significantly reduce the effectiveness of the electrode, such is the case with the DC pulsed reactive sputtered iridium oxide films presented herein.

Furthermore, the iridium oxide films deposited through DC pulsed reactive sputtering provide significant advantages compared to other iridium oxide films as described further below.

The micro-neuroelectrodes of the present invention can be any configuration and size which are suitable for recording and/or stimulation of neurons. Such electrodes can be of a variety of geometries, including two-dimensional and three-dimensional (or out-of-plane) micro-neuroelectrodes. In a specific embodiment, the micro-neuroelectrode can be an array of individually addressable microelectrodes. Non-limiting examples of suitable electrodes can include microelectrode arrays such as the Utah Electrode Array (hereinafter “UEA”), slanted Utah Electrode Array, single point electrodes, convoluted electrode array having tips which fall along a non-planar surface (e.g. trough, saddle, cylindrical, etc.), and the like. Furthermore, the electrodes can be configured in a non-planar or planar configuration. Specifically, the UEA is a non-planar configuration where the electrodes are formed three-dimensionally from a starting material. In contrast, a planar electrode is one which is formed in a plane of a starting material and then etched out and arranged into a usable array or other configuration. Planar electrodes (like the Michigan electrode array) can have more than one active surface. For example, there are 16 active sites in a conventional Michigan electrode array. Planar electrodes can also be penetrating electrodes or surface contact electrodes. The micro-neuroelectrodes of the present invention can also be formed of a suitable base material. The base material can be electrically conductive or insulative, as long as the coating or other feature provides an electrically conductive pathway along the electrode. Non-limiting examples of suitable electrode base materials can include silicon, metals (iridium, platinum, titanium, titanium tungsten, gold, etc.), conductive polymers, biodegradable polymers, and non-conductive plastics when coated with a conductive layer.

Prior to film formation, the surface of the micro-neuroelectrode can be pre-treated and/or cleaned. Such pretreatments can include any method which removes debris, native oxide, or other undesired material from the surface sufficient to provide ohmic contact with the sputtered iridium oxide film. Suitable pretreatments can include, but are not limited to, buffered oxide etch (BOE), ultrasonic cleaning, back sputtering or etching, such as plasma etching, and the like.

In one embodiment, the surface can be subjected to direct current sputtering at 50 kW to 300 kW for 1 to 20 minutes at a pressure of 5 mtorr to 100 mtorr, and in an Ar or other inert atmosphere. In a particular embodiment, the deposition conditions and the micro-neuroelectrode can be selected for the film to adhere directly to the surface of the micro-neuroelectrode.

Depending on the micro-neuroelectrode and the desired use, it may be useful to mask a portion of the surface of the micro-neuroelectrode. Any material that can effectively adhere to the surface of the micro-neuroelectrode, and can prevent formation of the film on the masked portion of the surface can be used. Non-limiting examples of masking materials that can be used include, but are not limited to, aluminum foil, polymer such as photoresist, metal such as aluminum, titanium, or shadow mask etc. This can be beneficial in order to selectively coat surfaces of the electrodes. This can increase selectivity of the electrode for fewer neurons and/or protect other portions of the electrode and/or its corresponding support structure. Suitable masking techniques can include, but are not limited to, photoresist, sacrificial layers, and the like.

In yet another additional optional embodiment, the surface can be prepared by depositing an intermediate layer thereon. Suitable intermediate layers can be formed of a material which provides adhesion of the SIROF to the underlying substrate, can form ohmic contact, and is preferably non-toxic. Non-limiting examples of suitable intermediate layers can include titanium, tungsten, titanium-tungsten alloy, platinum etc. Although the thickness may vary, suitable thicknesses can often range from about 5 nm to about 100 nm, and often about 50 nm or less. The intermediate layer can be deposited using any suitable technique such as, but not limited to, sputtering, chemical vapor deposition, electrodeposition, and the like.

Once the surface of the micro-neuroelectrode is properly prepared, pulsed direct current (DC) sputtering can be used to form the film. A sputtering machine having a pulsed DC generator and two inlet gas lines for oxygen and an inert gas which are operatively connected thereto can be used. Typically, the sputtering target can be a substantially pure iridium target although other iridium targets could also be used. In one specific embodiment, the iridium target can be a 3 inch diameter, 0.125 inch thick iridium (99.98% pure) sputtering target commercially available, e.g., from Kurt J. Lesker Company, although other diameter and thickness sizes can also be suitable.

Various sputtering parameters can be altered to vary the properties of the deposited film. Non-limiting examples of variable parameters can include sputtering power, sputtering pressure, gas flow, gas flow ratio, frequency, target temperature, chamber temperature, and the like. Sputtering pressure and sputtering power can significantly affect thin film stress, which stress can be compressive or tensile. Low stress and a clean surface of the microelectrodes increase film adherence. Typically, lower pressure makes the film relatively more compressive while relatively higher pressure makes the film tensile. Sputtering pressure can range from 4 mTorr to 50 mTorr. Furthermore, gas flow rates can affect the degree of crystallinity in the film, i.e. amorphous, polycrystalline or single crystalline. For example, a low gas flow (10 sccm) can result in an amorphous film and a relatively higher gas flow rate (100 sccm) can result in polycrystalline films. The frequency of the pulsed DC can also affect the crystal phases of the polycrystalline film.

As a general guideline, pulses having a sputtering power from about 50 W to about 500 W can be used, and in some case from about 90 W to about 110 W. In one specific embodiment, the pulsed DC can have a sputtering power of about 100 W. As a further non-limiting example, the frequency can range from about 50 KHz to about 250 KHz, and in some cases from 80 KHz to 150 KHz. The reactive sputtering temperature and pressure can be altered according to the desired film, and in relation to each other and other parameters. In one embodiment, the reactive conditions can include a sputtering pressure from about 4 mtorr to about 80 mtorr, and in some cases from about 30 mtorr to about 50 mtorr.

Various reactive conditions can dictate at least some of the physical properties of the resulting film. One condition in particular is the ratio of inert gas to oxygen flow rate. In one aspect, the ratio of inert gas to oxygen flow rate during film formation can be from about 0.5 to about 2.0 In a further aspect, the ratio of inert gas to oxygen flow rate during film formation can be about 1:1. The inert gas is used to create and sustain the plasma. Inert gas (Ar) generally impacts the iridium target to cause atoms of iridium to be removed. This iridium molecule or atom travel towards the substrate (e.g. a UEA) and are deposited on the substrate (e.g. at a tip of an electrode). While traveling iridium atoms react with oxygen to form iridium oxide which eventually gets deposited on the tips of electrode. A decrease in oxygen flow will favor deposition of pure iridium metal on the substrate which is not desirable. Increased oxygen can reduce pure metal deposition. Inert gases which can be included in the reaction chamber alone or in combination can include, but are not limited to, argon, nitrogen, and the like.

As with other parameters, the deposition rate and deposition time can affect the resulting film. Such conditions depend on the materials used, and the surface of the micro-neuroelectrode. In one aspect, the film can be deposited at a deposition rate from about 5 nm/min to about 100 nm/min. Deposition can continue until the film is the desirable thickness. In one aspect, the sputtering can be substantially complete in less than about 60 minutes. The resulting film can be continuous or semi-continuous over individual electrodes. The desirable film thickness can vary depending on the micro-neuroelectrode and the anticipated environment for use. The film thickness can also be adjusted based on sputtering time and other conditions. As a general guideline, the film can have an average thickness of about 50 nm to about 1000 nm, although films having a thickness from about 300 to about 600 nm are particularly useful. In one specific embodiment, a good iridium oxide film was formed using a sputtering pressure of 10 mTorr, 100 Watt power, 100 kHz frequency, an oxygen flow rate of 100 sccm, an argon flow rate of 100 sccm, and a deposition time of 20 minutes to achieve a film thickness of about 500 nm.

After the film is formed, it can be optionally annealed. Annealing temperatures can also play an important role in film adherence to the microelectrode surface. The annealing temperature can vary depending on the composition of the electrode and the film. In one embodiment, the film can be annealed at a temperature ranging from about 200° C. to about 1000° C. The films can be annealed at inert atmosphere like argon or nitrogen or the films can be annealed in oxygen or hydrogen atmosphere.

The films created according to the methods described herein can effectively coat a micro-neuroelectrode to provide stability in a harsh environment such as in a biological system. Furthermore, the particular coating methods utilized herein can form a film having superior performance properties over other stability-imparting films, either of different composition, or similar iridium-based composition formed by a different deposition method. Such properties include low impedance, thus allowing the micro-neuroelectrode to function in a manner superior to similar micro-neuroelectrodes having different coatings. In one aspect, the impedance of the film can be less than about 20 kΩ. In a further aspect, the average impedance of the film can be less than about 10 kΩ. For comparison, an AIROF or anodic iridium oxide film, having similar composition, but different deposition techniques has an average impedance of about 100 kΩ.

The film can have an average cathodal charge storage capacity of about 25 mC/cm² to about 70 mC/cm². To compare, a conventional AIROF film previously referred would have an average charge capacity of about 10 to 12 mC/cm². The micro-neuroelectrode can, in one embodiment, have a storage capacity of at least three times a AIROF film having a same thickness, and in some cases at least four times greater. A greater charge capacity can be a very desirable feature for micro-neuroelectrodes and results in superior functionality of an electrode. In addition, the pulse-DC SIROF has an increased charge injection capacity compared to AIROF. In particular, charge injection capacity is the integral of stimulus current over time divided by active surface area (mC/cm²), i.e. charge injection capacity is (stimulus current×time)/surface area. In some embodiments, depending on thickness, the charge injection capacity can range from about 0.1 to about 10 mC/cm², and in some cases from 4 to about 10 mC/cm². As a general guideline, it has been recognized that the charge storage capacity increases with film thickness while charge injection capacity decreases. Although other variables can also affect these values, in one embodiment the pulse-DC SIROF film can be from about 300 nm to about 600 nm, however other thicknesses can also be useful. Furthermore, DC sputtered iridium oxide films can have an internal stress from about 35 to about 120 MPa, and some cases from about 50 to about 80 MPa. Similarly, the iridium oxide films of the present invention can have a density from about 8 gm/cm³ to about 12 gm/cm³, and often within 5% of 10 gm/cm³.

Effective and safe evoking of threshold can be an important consideration for micro-neuroelectrode performance. Beyond limiting potential damage caused by high stimulating voltage, lowering the stimulating voltage and/or threshold duration of a micro-neuroelectrode can allow for use of the micro-electrodes in specialized environments and locations and can allow for extended use of such electrodes. If micro-neuroelectrodes have a high threshold duration and/or stimulating voltage, then the stimulation site may receive a burst of energy greater than is healthy, and even in an amount that is lethal to the cells or tissues of the site, e.g. electrolysis of water. Lowering the threshold duration and/or stimulating voltage, however, allows for greater precision, and inclusion in specialized areas such as the brain. In one aspect, the stimulus duration for threshold of the electrode through the film is less than about 20% of a threshold duration of the same electrode through an AIROF film of a same thickness, and in some cases less than about 10%. For example, under a 1.3 V stimulating voltage, the threshold duration for an AIROF film is about 50 μsec while for the sputtered iridium oxide film of the present invention at substantially the same conditions and electrode materials, the threshold is about 2 μsec. Thus, in some embodiments of the present invention, the iridium oxide coated micro-neuroelectrodes of the present invention can have a threshold duration from about 1 μsec to about 10 μsec and in some cases less than about 4 μsec for a 1.3 V stimulating voltage. Charge injection measurement is typically done in vitro while the duration to get a response in the tissue is obtained in vivo.

Safe electrical stimulation of the nervous system also generally requires reversible charge injection processes. Typically, this can be the result of utilizing double-layer capacitance and reversible faradaic processes which are confined to the electrode surface. Charge injection by any other faradaic reactions will be at least partially irreversible because products will tend to escape from the electrode surface. Irreversible faradaic reactions include water electrolysis, saline oxidation, metal dissolution and oxidation of organic molecules. However, in iridium oxide the faradaic reactions are confined within the oxide film and hence there are substantially no redox products to diffuse away from the electrode surface. Furthermore, the electrodes can include a protective coating such as parylene or other material which can be coated over the electrode and leaving the tip or active surface exposed. This can help to improve selectivity of the electrode to stimulation of fewer neurons, and in some cases one neuron. Thus, the pulse-DC SIROF material of the present invention allows for use of the micro-neuroelectrodes under reversible charge injection conditions.

As noted previously, the film can generally be polycrystalline. In one aspect, the film can have a high crystallinity where the dominant crystal face is (101). Without being bound to any particular theory, it is believed that the crystallinity of the film may beneficially affect the physical properties of the film, particularly those related to charge capacity, threshold, and impedance. It is also thought that the polycrystalline nature of the film is at least partially responsible for the vast difference between the pulsed DC sputtered iridium oxide film and similar films.

The pulsed DC iridium oxide films of the present invention can be optionally electrochemically treated to further improve charge storage capacity. In one aspect, the polycrystalline iridium oxide film can be electrochemically pulsed to form a stabilized polycrystalline iridium oxide film. Generally, this treatment can include applying a potentiodynamic condition to the polycrystalline iridium oxide film sufficient to increase cathodal charge storage capacity and decrease non-IrO₂ iridium content. In one aspect, the film can have a non-IrO₂ content less than the IrO₂ iridium content. As a general rule, it has been found that the SIROF film, as deposited, includes substantial amounts of iridium in various oxidation states, e.g. Ir metal, Ir₂O, IrO, Ir₂O₃, IrO₂ and Ir₂O₅. Except Ir²⁺ and Ir³⁺, other species do not appear to contribute to performance of the film. Reduction and/or substantial elimination of these species can involve use of an electrosolution having a reference electrode and a counter electrode in addition to the SIROF coated micro-neuroelectrode.

As one example, the SIROF film after deposition, without further treatment, can have cathodal charge storage capacity (CCSC) of about 27.74 mC/cm² which is more than twice that of AIROF (10-12 mC/cm²). The SIROF CCSC can be increased further by electrochemical pulsing. The pulsing can be in the form of any suitable pulsed waveform such as, but not limited to, triangular, rectangular, irregular, bell curve, and the like. In one embodiment, triangular pulse waveforms have proven very effective. The SIROF electrode can be activated by potentiodynamic pulsing, e.g. between −0.8 and +0.8 V with respect to the reference electrode (e.g. Ag/AgCl). Platinum can be used as a counter electrode, although other conductive materials can also be used. All three electrodes are immersed in phosphate buffered saline (PBS) solution or other suitable electrosolution. After 200 cycles at a frequency of 1 Hz the CCSC of SIROF can further be increased to 38 mC/cm², which represents an additional 40% increase.

Covered electrodes including a film of iridium oxide deposited by pulsed DC sputtering means can endure harsh environments. One such environment is a biological environment, including insertion or inclusion within mammalian tissue. In one aspect, the film can have a corrosion resistance sufficient to withstand exposure to (e.g., chronic implantation) neurotissue for a period of at least two months and often more than twelve months. The long term stability of the film goes beyond preventing corrosion of the micro-neuroelectrode. Specifically, the physical properties of the film can be retained for extended periods of time. In one embodiment, the impedance of the film degenerates (i.e. increases) by less than 5%, and typically less than 10% over 12 weeks in a biological environment. In some embodiments, the impedance can be substantially maintained, i.e. statistically no change. Similarly, the films of the present invention can maintain good charge storage capacity upon exposure to a biological environment. Generally, the films can have a reduction in charge capacity of less than 5% and often less than 10% over 12 weeks exposure to the biological environment. In some embodiments, the charge storage capacity can be substantially maintained, i.e. statistically no change. These ranges are based on exposure to a biological environment of phosphate buffered saline (PBS) solution.

As such, the methods presented herein represent a relatively fast and potentially economical method of coating micro-neuroelectrodes. Previous coating methods, such as the AIROF, tend to be very time consuming, and produces a film of questionable in-vivo stability. The pulsed DC sputtered iridium oxide film presented herein can be effectively utilized to coat micro-neuroelectrodes, specifically micro-neuroelectrodes that are configured to record and/or stimulate neurons. Additionally, the films presented herein have low impedances, thus neural probes of a micro-neuroelectrode having coated tips can have low exposure to the harsh biological environment, and at the same time have low impedance, thereby leading to more selectivity in stimulation and recording. The films provide stability in that the films are stable, based on both in-vitro and in-vivo experimentation. Further, the iridium oxide films formed through pulsed DC sputtering have more storage capacity than conventional iridium films, such as AIROF.

### EXAMPLES

The following examples illustrate various methods of preparing micro-neuroelectrodes in accordance with the present invention. However, it is to be understood that the following are only exemplary or illustrative of the application of the principles of the present invention. Numerous modifications and alternative compositions, parameters, methods, and systems can be devised by those skilled in the art without departing from the spirit and scope of the present invention. The appended claims are intended to cover such modifications and arrangements. Thus, while the present invention has been described above with particularity, the following Examples provide further detail in connection with several specific embodiments of the invention.

### Example 1

Sputtered iridium oxide films were deposited on test structures, including a micro-neuroelectrode that is an array of individually addressable microelectrodes (specifically, a micro-neuroelectrode known as a Utah Electrode Array, or UEA). Pulsed DC was used at 100 W and with a ratio of argon to oxygen flow rate maintained at 1:1. Sputtering pressure was 10 mTorr and sputtering time was 20 min. The thickness achieved was 500 nm on the flat monitor test wafers.

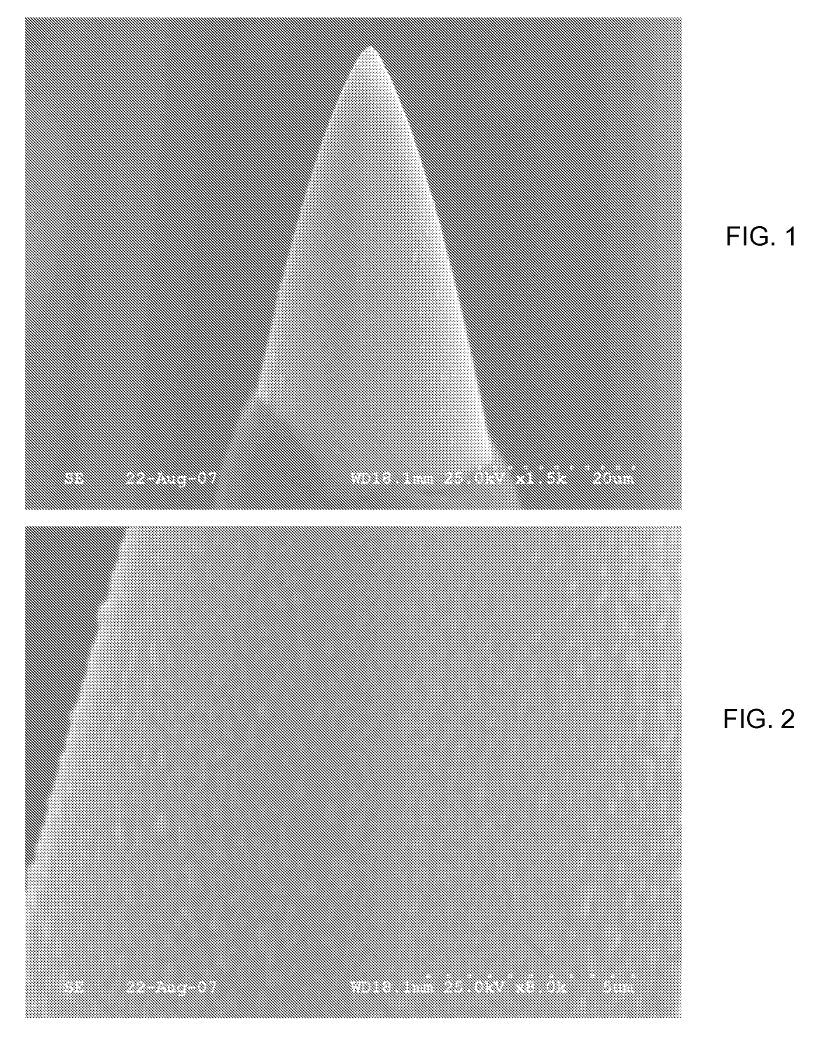

The films were annealed at 400° C. for 2 hours with an oxygen flow rate of 2 slpm. An x-ray diffraction (XRD) study showed that the sputtered films were polycrystalline with <101> peak of highest intensity. FIG. 1 is an SEM of one coated UEA electrode tip. FIG. 2 shows a magnified view of the coating which shows some texture although the overall coating is relatively smooth.

### Example 2

### Electrochemical Properties of Coated Electrodes of Example 1

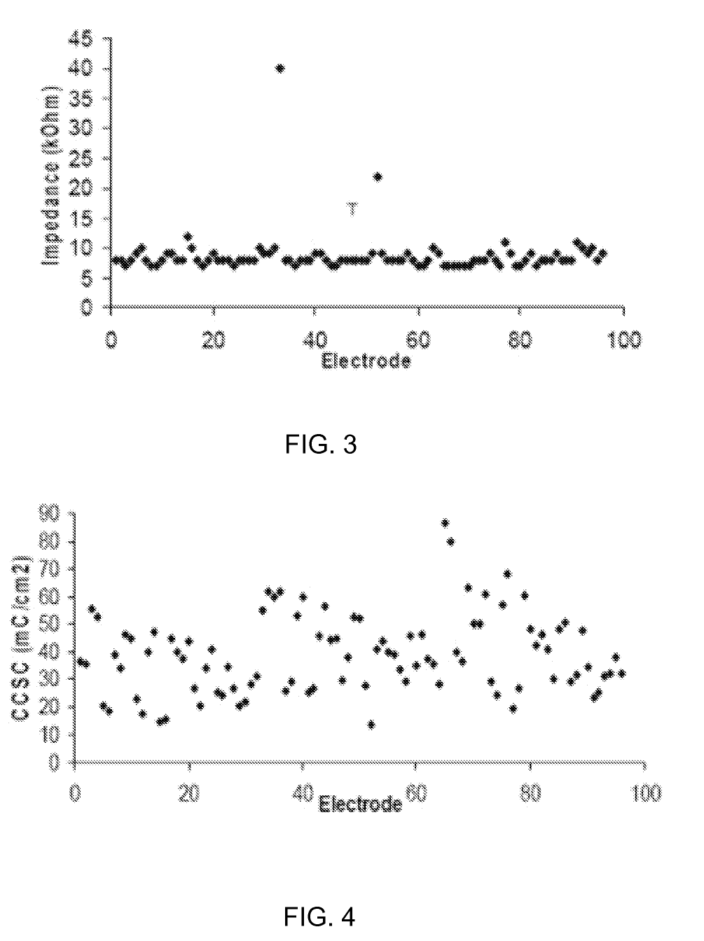

An electrochemical characterization was carried out on the coated UEA of Example 1. Low impedance of around 8 kΩ was attained as illustrated in FIG. 3. FIG. 3 shows the average electro-chemical impedance of 96 electrodes of the UEA. The average impedance was 8.7 kΩ and 1 kHz with a standard deviation of 3.65 kΩ. A comparative example film (AIROF) on a UEA and was tested to have an impedance of 100 kΩ.

FIG. 4 shows the cathodal charge storage capacity (CCSC) calculated for each electrode in a coated UEA micro-neuroelectrode. The average CCSC in the iridium oxide film was observed to be 38.98 mC/cm² while the comparative AIROF was observed to be about 10 mC/cm².

### Example 3

### In-Vitro Experiments with Electrodes of Example 1

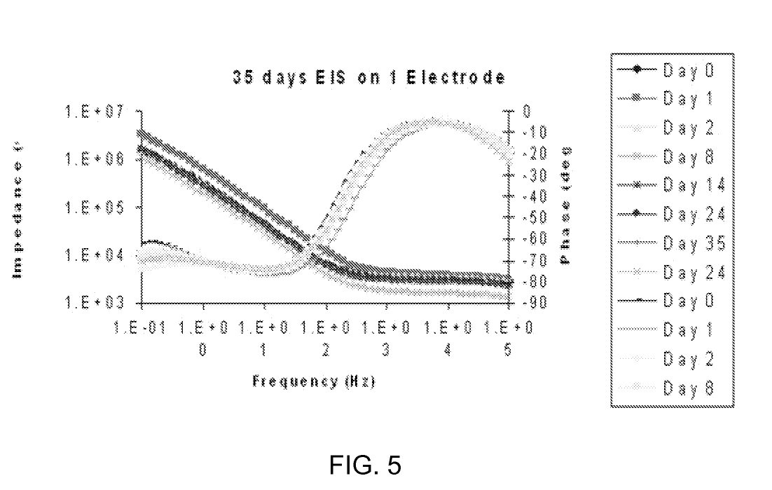

In order to investigate the long term stability of the pulsed DC sputtered iridium oxide films, the UEA was soaked in a phosphate buffered saline (PBS) solution for 35 days and continuously monitored by measuring the impedance across randomly picked 24 electrodes. After 35 days of study, no change in impedance was observed which illustrates the stability of the film. Results of the testing are illustrated in FIG. 5. Specifically, FIG. 5 is a Bode plot of one electrode of UEA soaked in PBS solution for 35 days.

### Example 4

### In-Vivo Experiments with Electrodes of Example 1

The UEA of Example 1, sputter coated with iridium oxide, was implanted in the peripheral sciatic nerve of a cat. For stimulation, the median stimulus duration for threshold was shorter than that of the conventional AIROF coated UEA. Typically stimulus duration for the pulse DC sputter coated UEA was 1-2 μsec at 1.3 V, while conventionally for UEA coated with AIROF, stimulus duration is 5-10 μsec, thus indicating that the charge injection storage capacity of the films presented by the present disclosure are substantially better than conventional AIROF.

It is to be understood that the above-described arrangements are only illustrative of the application of the principles of the present invention. Numerous modifications and alternative arrangements may be devised by those skilled in the art without departing from the spirit and scope of the present invention and the appended claims are intended to cover such modifications and arrangements. Thus, while the present invention has been described above with particularity and detail in connection with what is presently deemed to be the most practical and preferred embodiments of the invention, it will be apparent to those of ordinary skill in the art that numerous modifications, including, but not limited to, variations in size, materials, shape, form, function, and manner of operation, assembly, and use may be made without departing from the principles and concepts set forth herein.

What is claimed is:

1. A method of coating a micro-neuroelectrode, comprising:
sputtering a film of iridium oxide on a surface of the micro-neuroelectrode, said reactive sputtering occurring using pulse-DC conditions under reactive conditions sufficient to form a polycrystalline iridium oxide film adhering to the surface of the micro-neuroelectrode.

2. The method of claim 1, further comprising masking at least a portion of the surface of the micro-neuroelectrode prior to sputtering the film.

3. The method of claim 1, further comprising annealing the polycrystalline iridium oxide film.

4. The method of claim 1, wherein the reactive conditions include a ratio of inert gas to oxygen flow rate during film formation of from about 0.5 to about 2.0.

5. The method of claim 1, wherein the reactive conditions include a sputtering pressure from about 4 mtorr to about 80 mtorr.

6. The method of claim 1, wherein the film is a continuous polycrystalline film.

7. The method of claim 6, wherein the surface is silicon and the film has a dominant crystal phase of (101).

8. The method of claim 1, wherein the film is deposited at a deposition rate from about 5 nm/min to about 100 nm/min.

9. The method of claim 1, further comprising the step of electrochemical pulsing of the polycrystalline iridium oxide film to form an activated polycrystalline iridium oxide film having an increased cathodal charge storage capacity and decreased non-IrO₂ iridium content.

10. The method of claim 9, wherein the electrochemical pulsing includes applying a potentiodynamic condition to the micro-neuroelectrode having the polycrystalline iridium oxide film in an electrosolution using a reference electrode and a counter electrode.

11. The method of claim 10, wherein the potentiodynamic condition is a triangular pulse waveform.

12. A coated micro-neuroelectrode, comprising:
a micro-neuroelectrode having a surface configured to interface with biological matter;
a polycrystalline iridium oxide film adhered to at least a portion of the surface configured to interface with biological matter, said iridium oxide film having an impedance of less than about 20 kΩ.

13. The micro-neuroelectrode of claim 12, wherein the film has a thickness of about 50 nm to about 1000 nm.

14. The micro-neuroelectrode of claim 12, wherein the average charge capacity of the film is about 25 mC/cm² to about 70 mC/cm².

15. The micro-neuroelectrode of claim 12, further comprising an intermediate titanium film between the iridium oxide film and the surface of the micro-neuroelectrode.

16. The micro-neuroelectrode of claim 15, wherein an interface between the iridium oxide film and the surface has an internal stress from about 50 to about 120 MPa.

17. The micro-neuroelectrode of claim 12, wherein the polycrystalline iridium oxide film has a dominant crystal face of (101).

18. The micro-neuroelectrode of claim 12, wherein the film has a corrosion resistance sufficient to withstand exposure to neurotissue for a period of at least twelve months.

19. The micro-neuroelectrode of claim 12, wherein the micro-neuroelectrode is an array of individually addressable microelectrodes.

20. The micro-neuroelectrode of claim 12, wherein the impedance of the film degenerates by less than 5% in a biological environment.

21. The micro-neuroelectrode of claim 12, wherein a stimulus duration for threshold of the electrode through the film is less than about ½ of a similar stimulus duration for threshold of the same electrode through an AIROF film of a same thickness.

22. The micro-neuroelectrode of claim 12, wherein the film has a charge storage capacity of at least three times of an AIROF film having a same thickness.

23. The micro-neuroelectrode of claim 12, wherein the film has a charge injection capacity of about 0.1 mC/cm² to about 10 mC/cm².

24. The micro-neuroelectrode of claim 12, wherein the film has non-IrO₂ iridium content less than the IrO₂ iridium content.
